(19) United States
(12) Patent Application Publication
(10) Pub. No.: US 2009/0085579 A1
(43) Pub. Date: Apr. 2, 2009

(54) ATTENUATION APPARATUS AND TEST APPARATUS

(75) Inventors: Hiroaki TAKEUCHI, TOKYO (JP); Yoshiyuki HATA, TOKYO (JP); Makoto Nakanishi, TOKYO (JP)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: ADVANTEST CORPORATION, TOKYO (JP)

(21) Appl. No.: 11/864,894

(22) Filed: Sep. 28, 2007

(51) Int. Cl. H03K 5/08; G01R 31/28

(52) U.S. Cl. 324/555; 327/309

(57) ABSTRACT

There is provided an attenuation apparatus for attenuating a signal received via a first terminal thereof and outputting the attenuated signal via a second terminal thereof. The attenuation apparatus includes a first transmission path and a second transmission path which respectively have different attenuation amounts for the signal, a connection switching section that switches, between the first and second transmission paths, a transmission path connected to the first and second terminals so as to be positioned therebetween, and a first ground connection switching section that connects, to a reference potential, respective ends of the first transmission path and a contact point positioned on a path between the respective ends of the first transmission path, when the second transmission path is electrically connected to the first and second terminals so as to be positioned therebetween.

### BACKGROUND

1. Technical Field

The present invention relates to an attenuation apparatus and a test apparatus. More particularly, the present invention relates to an attenuation apparatus for attenuating a received signal and outputting the attenuated signal, and to a test apparatus for testing a device under test.

2. Related Art

A known attenuation apparatus for attenuating a signal and outputting the attenuated signal includes therein a pass-through-side path that passes the signal therethrough and an attenuator-side path that attenuates the signal and outputs the attenuated signal, as disclosed in Unexamined Japanese Patent Application Publication No. 2001-7672, for example.

Such an attenuation apparatus selects whether to pass the signal therethrough or attenuate the signal and output the attenuated signal, by selecting one of the pass-through-side path and the attenuator-side path. The constituent for selecting one of the paths can be realized by using a switch which is a semiconductor transistor, for example.

However, the above-described attenuation apparatus has a problem. When the attenuation apparatus selects the attenuator-side path to attenuate the signal by a predetermined attenuation amount, for example, the pass-through-side path is not sufficiently isolated. Therefore, the signal may be leaked and transmitted via the pass-through-side path. If such occurs, the signal which is attenuated by the predetermined attenuation amount by the attenuator-side path is combined with the signal that is leaked via the pass-through-side path. This makes it difficult to accurately control the attenuation amount of the signal.

Here, the attenuation apparatus may be utilized in an apparatus for testing a device under test such as a semiconductor circuit, a network analyzer for measuring characteristics of a device under test and other apparatuses, in order to attenuate a test signal to be supplied to the device under test so that the test signal has a predetermined amplitude. However, the use of the above-described attenuation apparatus in the above-mentioned apparatuses makes it difficult to accurately control the amplitude of the test signal. Therefore, the test apparatus has difficulties in accurately testing the device under test, and the network analyzer has problems in accurately measuring the characteristics of the device under test.

### SUMMARY

Therefore, it is an object of an aspect of the present invention to provide an attenuation apparatus and a test apparatus, which are capable of overcoming the above drawbacks accompanying the related art. The above and other objects can be achieved by combinations described in the independent claims. The dependent claims define further advantageous and exemplary combinations of the present invention.

According to a first aspect related to the innovations herein, one exemplary attenuation apparatus may include an attenuation apparatus for attenuating a signal received via a first terminal thereof and outputting the attenuated signal via a second terminal thereof. The attenuation apparatus includes a first transmission path and a second transmission path which respectively have different attenuation amounts for the signal, a connection switching section that switches, between the first and second transmission paths, a transmission path connected to the first and second terminals so as to be positioned therebetween, and a first ground connection switching section that connects, to a reference potential, respective ends of the first transmission path and a contact point positioned on a path between the respective ends of the first transmission path, when the second transmission path is electrically connected to the first and second terminals so as to be positioned therebetween.

According to a second aspect related to the innovations herein, one exemplary test apparatus may include a test apparatus for testing a device under test. The test apparatus includes a waveform generating section that generates a test signal to be supplied to the device under test, an attenuating section that attenuates the test signal, a supply section that supplies the attenuated test signal to the device under test, and a sampling section that samples a waveform of a response signal which is output from the device under test in response to the test signal. Here, the attenuating section includes a first transmission path and a second transmission path which respectively have different attenuation amounts for a signal, a connection switching section that switches, between the first and second transmission paths, a transmission path connected to a first terminal that receives a signal and a second terminal that outputs a signal so as to be positioned between the first and second terminals, and a first ground connection switching section that connects, to a reference potential, respective ends of the first transmission path and a contact point positioned on a path of the first transmission path, when the second transmission path is electrically connected to the first and second terminals so as to be positioned therebetween.

The summary clause does not necessarily describe all necessary features of the embodiments of the present invention. The present invention may also be a sub-combination of the features described above. The above and other features and advantages of the present invention will become more apparent from the following description of the embodiments taken in conjunction with the accompanying drawings.

### BRIEF DESCRIPTION OF THE DRAWINGS

FIG. 1 illustrates an exemplary configuration of an attenuation apparatus 100 relating to an embodiment of the present invention.

FIG. 2 illustrates another exemplary configuration of the attenuation apparatus 100.

FIG. 3 illustrates an exemplary configuration of the attenuation apparatus 100 in detail.

FIG. 4 illustrates an exemplary configuration of a test apparatus 200 relating to an embodiment of the present invention.

### DESCRIPTION OF EXEMPLARY EMBODIMENTS

Hereinafter, an aspect of the present invention will be described through some embodiments. The embodiments do not limit the invention according to the claims, and all the combinations of the features described in the embodiments are not necessarily essential to means provided by aspects of the invention.

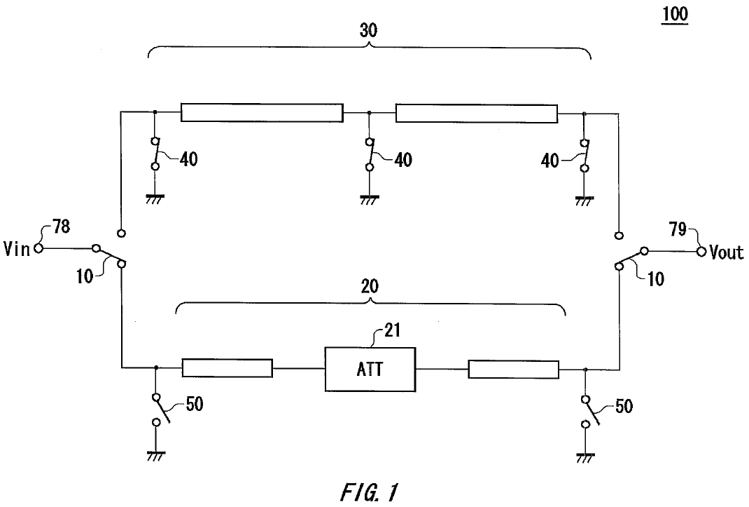

FIG. 1 illustrates an exemplary configuration of an attenuation apparatus 100 relating to an embodiment of the present invention. The attenuation apparatus 100 attenuates the amplitude of a signal received via a first terminal 78 by a predetermined attenuation amount (including 0 dB), and outputs the attenuated signal via a second terminal 79. The attenuation apparatus 100 includes therein the first terminal 78, the second terminal 79, a first transmission path 30, a second transmission path 20, a connection switching section 10, a first ground connection switching section 40, and a second ground connection switching section 50.

The first terminal 78 receives, from outside, a signal the amplitude of which is to be attenuated by the attenuation apparatus 100. The second terminal 79 outputs, to outside, the signal the amplitude of which has been attenuated by the attenuation apparatus 100.

The first transmission path 30 and the second transmission path 20 are provided in parallel with each other so as to be positioned between the first and second terminals 78 and 79. The first and second transmission paths 30 and 20 respectively attenuate the signal received at the first terminal 78 by different attenuation amounts, and transmit the attenuated signals to the second terminal 79.

For example, the first transmission path 30 may be a wire that electrically connects the first and second terminals 78 and 79 to each other, and the second transmission path 20 may be a path that provides an attenuator 21 having a predetermined attenuation amount between the first and second terminals 78 and 79. Which is to say, the first transmission path 30 may have an attenuation amount of substantially 0 dB, and the second transmission path 20 may have an attenuation amount larger than the attenuation amount of the first transmission path 30. As an alternative example, the attenuator 21 may be provided on the first transmission path 30. If such is the case, the attenuation amount of the second transmission path 20 may be set at substantially 0 dB.

The connection switching section 10 switches, between the first and second transmission paths 30 and 20, the transmission path that is connected to the first and second terminals 78 and 79 so as to be positioned therebetween. Such a configuration makes it possible to select the attenuation amount of the attenuation apparatus 100. The connection switching section 10 may include, for example, a switch for switching, between the first and second transmission paths 30 and 20, the transmission path connected to the first terminal 78 and a switch for switching, between the first and second transmission paths 30 and 20, the transmission path connected to the second terminal 79. The switches included in the connection switching section 10 operate in synchronization with each other so as to select the same one of the first and second transmission paths 30 and 20.

The first ground connection switching section 40 connects predetermined points of the first transmission path 30 to a reference potential when the connection switching section 10 selects the second transmission path 20 and connects the second transmission path 20 to the first and second terminals 78 and 79. In more detail, when the connection switching section 10 selects the second transmission path 20, the first ground connection switching section 40 connects, to the reference potential, the respective ends of the first transmission path 30 and a contact point positioned on the transmission path between the respective ends of the first transmission path 30. The reference potential may be a ground potential, for example. In FIG. 1, the contact point is positioned in substantially the middle between the respective ends of the first transmission path 30, as an example.

The first ground connection switching section 40 may include shunt switches which are respectively provided between the first transmission path 30 and the ground potential. The first ground connection switching section 40 may operate in synchronization with the connection switching section 10.

As described above, when the connection switching section 10 selects the second transmission path 20, the respective ends of the first transmission path 30 are connected to ground in the present embodiment. In this way, the leak component which is transmitted via the first transmission path 30 from the first terminal 78 to the second terminal 79 can be reduced. Furthermore, when the connection switching section 10 selects the second transmission path 20, the contact point positioned on the path of the first transmission path 30 is also connected to ground in the present embodiment. In this way, the above-mentioned leak component can be further reduced, and the noise component or the like which may be generated on the path of the first transmission path 30, for example, can be prevented from being transmitted to the second terminal 79. With the above-described configuration, even when the signal received at the first terminal 78 is attenuated by the attenuator 21 on the second transmission path 20 by a large attenuation amount, the degradation in the S/N ratio which may be caused by the noise component transmitted through the first transmission path 30 can be alleviated.

The second ground connection switching section 50 connects predetermined points on the second transmission path 20 to a reference potential when the connection switching section 10 selects the first transmission path 30 and connects the first transmission path 30 to the first and second terminals 78 and 79. In more detail, when the connection switching section 10 selects the first transmission path 30, the second ground connection switching section 50 connects the respective ends of the second transmission path 20 to the reference potential.

The second ground connection switching section 50 may include shunt switches which are respectively provided between the second transmission path 20 and the ground potential. With such a configuration, when the connection switching section 10 selects the first transmission path 30, the leak component which is transmitted via the second transmission path 20 from the first terminal 78 to the second terminal 79 can be reduced.

The second ground connection switching section 50 may additionally include a switch that switches whether to connect a contact point on the path of the second transmission path 20 to the ground potential, similarly to the first ground connection switching section 40. According to the present exemplary embodiment, the second transmission path 20 has a larger attenuation amount than the first transmission path 30. Therefore, the leak component or the like which is transmitted via the second transmission path 20 is also reduced by an amount determined in accordance with the attenuation amount of the second transmission path 20.

For the reason stated above, the second ground connection switching section 50 relating to the present embodiment is configured without a switch for switching whether to connect the contact point on the path of the second transmission path 20 to the ground potential, so that the wire of the second transmission path 20 is not connected to the reference potential. Being configured in this manner, the attenuation apparatus 100 does not require a switch for switching whether to connect the contact point on the path of the second transmission path 20 to the ground potential, thereby achieving a smaller circuit scale.

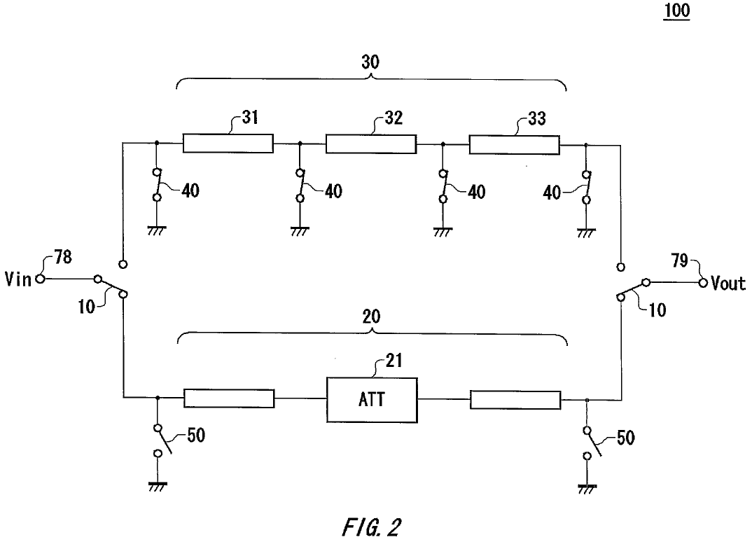

FIG. 2 illustrates another exemplary configuration of the attenuation apparatus 100. The attenuation apparatus 100 relating to the present example is different from the attenuation apparatus 100 described with reference to FIG. 1 in that a plurality of contact points positioned on the first transmission path 30 between the respective ends thereof are connected to the reference potential. Apart from this difference, the attenuation apparatus 100 relating to the present example may be the same as the attenuation apparatus 100 described with reference to FIG. 1.

The first ground connection switching section 40 relating to the present example connects, to the reference potential, the respective ends of the first transmission path 30 and a plurality of contact points positioned between the respective ends of the first transmission path 30 when the connection switching section 10 selects the second transmission path 20. According to the present example, the first ground connection switching section 40 may include a plurality of switches which are provided between the reference potential and the plurality of contact points positioned between the respective ends of the first transmission path 30. The above-described configuration can further improve the isolation of the first transmission path 30.

According to the present example, the switches included in the first ground connection switching section 40 divide the first transmission path 30 into a plurality of portions (indicated by the reference numerals 31, 32 and 33), as shown in FIG. 2. For example, the boundaries of the portions 31, 32 and 33 may be defined by the contact points on the path of the first transmission path 30 which are connected to the switches included in the first ground connection switching section 40.

The switches included in the first ground connection switching section 40 may be positioned in such a manner that the respective portions (31, 32 and 33) on the first transmission path 30 have the same characteristic impedance. For example, the switches included in the first ground connection switching section 40 may be positioned at a substantially equal interval, in a case where the first transmission path 30 has a uniform characteristic impedance when the first ground connection switching section 40 is not provided and where the switches included in the first ground connection switching section 40 have substantially the same capacitance component when being turned off.

The above-described configuration can reduce the reflection or the like which may be generated in the respective portions on the first transmission path 30 when the signal is transmitted through the first transmission path 30. As a result, the attenuation apparatus 100 relating to the present example can achieve both of the following effects. When the connection switching section 10 selects the first transmission path 30, the signal loss over the first transmission path 30 can be reduced. When the connection switching section 10 selects the second transmission path 20, the isolation of the first transmission path 30 can be improved.

Here, the portions 31, 32 and 33 are preferably formed so as to satisfy the relation ωL=1/ωC, where ωL denotes the reactance of the induction component of the transmission path in each of the portions 31, 32 and 33 of the first transmission path 30 and 1/ωC denotes the reactance of the capacitance component of the switch which is connected to a corresponding one of the portions when the switch is turned off. In other words, the respective portions may be formed in such a manner that the reactance of the transmission path within each portion, which is determined by the length and width of the transmission path within the portion, becomes substantially equal to the reactance of a corresponding one of the switches. For example, when the switches are transistors, the capacitance components of the switches which are observed when the switches are turned off can be obtained based on the specification information of the transistors such as their gate sizes. The respective switches included in the first ground connection switching section 40 may be positioned on the first transmission path 30 at an interval determined in accordance with their capacitance components obtained in advance.

With the above-described configuration, the induction component of the first transmission path 30 and the capacitance component of the first ground connection switching section 40 can offset each other. As a result, the first transmission path 30 can transmit a high-frequency signal.

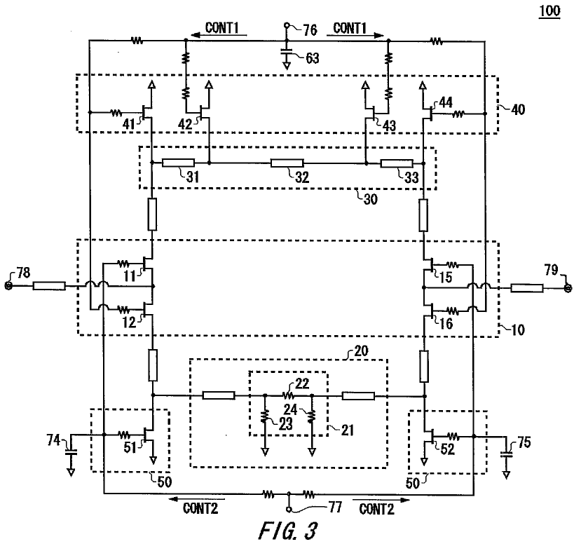

FIG. 3 illustrates an exemplary configuration of the attenuation apparatus 100 in detail. The attenuation apparatus 100 relating to the present example may be a circuit formed on a semiconductor substrate, for example. According to the configuration illustrated in FIG. 3, the semiconductor switches are shown as transistors of the same channel. However, the attenuation apparatus 100 can be configured in a similar manner even when the semiconductor switches are formed by transistors of different channels. The semiconductor switches may be, for example, high electron mobility transistors (HEMTs). According to a different example, the semiconductor switches may be field effect transistors (FETs) or pin diodes.

The attenuation apparatus 100 relating to the present example includes therein the first terminal 78, the second terminal 79, a first switching terminal 76, a second switching terminal 77, the first transmission path 30, the second transmission path 20, the connection switching section 10, the first ground connection switching section 40, and the second ground connection switching section 50. The first and second terminals 78 and 79 may be the same as the first and second terminals 78 and 79 described with reference to FIG. 1. The first and second switching terminals 76 and 77 respectively supply, to the connection switching section 10, a first control signal CONT1 and a second control signal CONT2 in order to control the selection to be made by the connection switching section 10 between the first and second transmission paths 30 and 20.

The connection switching section 10 connects one of the first and second transmission paths 30 and 20 to the first and second terminals 78 and 79 so as to be positioned therebetween, in response to the first and second control signals CONT1 and CONT2. The connection switching section 10 relating to the present example includes a plurality of semiconductor switches 11, 12, 15 and 16.

The semiconductor switches 11 and 12 receive the signal from the first terminal 78 and input the received signal into one of the first and second transmission paths 30 and 20 which is selected in accordance with the first and second control signals CONT1 and CONT2. The semiconductor switches 11 and 12 are provided in series between the starting point of the first transmission path 30 and the starting point of the second transmission path 20.

For example, the semiconductor switch 11 is connected to the starting point of the first transmission path 30 at the source terminal thereof, is connected to the first terminal 78 at the drain terminal thereof, and receives the second control signal CONT2 at the gate terminal thereof. In other words, the semiconductor switch 11 inputs the signal received from the first terminal 78 into the first transmission path 30 when controlled to be turned on by the second control signal CONT2. The semiconductor switch 11 does not input the signal received from the first terminal 78 into the first transmission path 30 when controlled to be turned off by the second control signal CONT2.

For example, the semiconductor switch 12 is connected to the starting point of the second transmission path 20 at the source terminal thereof, is connected to the first terminal 78 at the drain terminal thereof, and receives the first control signal CONT1 at the gate terminal thereof. In other words, the semiconductor switch 12 inputs the signal received from the first terminal 78 into the second transmission path 20 when controlled to be turned on by the first control signal CONT1. The semiconductor switch 12 does not input the signal received from the first terminal 78 into the first transmission path 30 when controlled to be turned off by the first control signal CONT1.

The first and second switching terminals 76 and 77 respectively output the first and second control signals CONT1 and CONT2 in such a manner that when one of the semiconductor switches 11 and 12 is turned on, the other is turned off. For example, when the semiconductor switches 11 and 12 are formed by using transistors of the same channel, the second switching terminal 77 may output the second control signal which is obtained by inverting the first control signal. With such a configuration, one of the first and second transmission paths 30 and 20 can be selected, and the signal can be input into the selected transmission path.

The semiconductor switches 15 and 16 are used to switch, between the first and second transmission paths 30 and 20, the transmission path connected to the second terminal 79. Similarly to the semiconductor switches 11 and 12, the semiconductor switches 15 and 16 are provided in series between the ending point of the first transmission path 30 and the ending point of the second transmission path 20.

For example, the semiconductor switch 15 is connected to the ending point of the first transmission path 30 at the source terminal thereof, is connected to the first terminal 78 at the drain terminal thereof, and receives the second control signal CONT2 at the gate terminal thereof. For example, the semiconductor switch 16 is connected to the ending point of the second transmission path 20 at the source terminal thereof, is connected to the first terminal 78 at the drain terminal thereof, and receives the first control signal CONT1 at the gate terminal thereof. With such a configuration, the semiconductor switches 15 and 16 can be used to select the same one of the first and second transmission paths 30 and 20 as the semiconductor switches 11 and 12 in synchronization with the semiconductor switches 11 and 12.

The first ground connection switching section 40 switches whether to connect the respective ends and contact points of the first transmission path 30 to the ground potential, in accordance with one of the first and second control signals CONT1 and CONT2. According to the present example, the first ground connection switching section 40 operates in accordance with the first control signal CONT1.

The first ground connection switching section 40 includes a plurality of semiconductor switches 41, 42, 43 and 44. The plurality of semiconductor switches 41, 42, 43 and 44 correspond to the switches included in the first ground connection switching section 40 which are described with reference to FIGS. 1 and 2.

The semiconductor switch 41 is provided between the starting point of the first transmission path 30 and the ground potential, and switches whether to connect the starting point of the first transmission path 30 to the ground potential. The semiconductor switch 44 is provided between the ending point of the first transmission path 30 and the ground potential, and switches whether to connect the ending point of the first transmission path 30 to the ground potential. The semiconductor switches 42 and 43 are provided between the ground potential and the corresponding contact points on the first transmission path 30 which are positioned between the respective ends of the first transmission path 30. The semiconductor switches 42 and 43 switch whether to connect the corresponding contact points to the ground potential.

For example, each of the semiconductor switches 41, 42, 43 and 44 is connected to the first transmission path 30 at the drain terminal thereof, is connected to the ground potential at the source terminal thereof, and receives the first control signal CONT1 at the gate terminal thereof. With such a configuration, the semiconductor switches 41, 42, 43 and 44 can switch whether to connect the corresponding points of the first transmission path 30 to the ground potential, in accordance with the selection made by the connection switching section 10 between the first and second transmission paths 30 and 20.

The second ground connection switching section 50 switches whether to connect the respective ends and contact points of the second transmission path 20 to the ground potential, in accordance with one of the first and second control signals CONT1 and CONT2. According to the present example, the second ground connection switching section 50 operates in accordance with the second control signal CONT2.

The second ground connection switching section 50 includes two semiconductor switches 51 and 52. The semiconductor switch 51 is provided between the starting point of the second transmission path 20 and the ground potential, and switches whether to connect the starting point of the second transmission path 20 to the ground potential. The semiconductor switch 52 is provided between the ending point of the second transmission path 20 and the ground potential, and switches whether to connect the ending point of the second transmission path 20 to the ground potential.

For example, each of the semiconductor switches 51 and 52 is connected to the second transmission path 20 at the drain terminal thereof, is connected to the ground potential at the source terminal thereof, and receives the second control signal CONT2 at the gate terminal thereof. With such a configuration, the semiconductor switches 51 and 52 can switch whether to connect the points on the second transmission path 20 to the ground potential, in accordance with the selection made by the connection switching section 10 between the first and second transmission paths 30 and 20.

The semiconductor switches 41, 11, 12 and 51 constitute a series shunt switch in such a manner that the semiconductor switches 11 and 12 are respectively connected in series with the corresponding transmission paths and the semiconductor switches 41 and 51 are respectively connected in shunt with the corresponding transmission paths. Similarly, the semiconductor switches 44, 15, 16 and 52 constitute a series shunt switch.

The above-described exemplary configuration can reduce the leak component transmitted from the first terminal 78 to the second terminal 79 via each of the first and second transmission paths 30 and 20 as described with reference to FIGS. 1 and 2. In particular, the exemplary configuration can reduce the leak component transmitted via the first transmission path 30 which has a smaller attenuation amount.

As illustrated in FIG. 3, the attenuation apparatus 100 may further include therein a capacitor 63, a capacitor 74, and a capacitor 75. The capacitor 63 is provided between the ground potential and a control signal line for transmitting the first control signal CONT1. For example, the capacitor 63 may be provided in the vicinity of the first switching terminal 76 so as to be positioned between the control signal line and the ground potential.

The capacitors 74 and 75 are each provided between the ground potential and a control signal line for transmitting the second control signal CONT2. For example, the capacitor 74 may be provided in the vicinity of the gate terminal of the semiconductor switch 51 so as to be positioned between the control signal line and the ground potential. The capacitor 75 may be provided in the vicinity of the gate terminal of the semiconductor switch 52 so as to be positioned between the control signal line and the ground potential. With the above-described capacitors being provided, the attenuation apparatus 100 can reduce the high-frequency noise occurring on the control signal lines. As a result, the semiconductor switches included in the first and second ground connection switching sections 40 and 50 can operate stably.

As illustrated in FIG. 3, the attenuation apparatus 100 may have resistances and wires which are positioned in such a manner that the resistance component is substantially the same between the first switching terminal 76 and the gate terminal of each of the semiconductor switches 12, 41, 42, 43, 44, and 16. Furthermore, the attenuation apparatus 100 may have resistances and wires which are positioned in such a manner that the resistance component is substantially the same between the second switching terminal 77 and each of the semiconductor switches 11, 51, 52 and 15. With such a configuration, the respective semiconductor switches can accurately operate.

Referring to the first ground connection switching section 40, the semiconductor switches 51 and 52 connected to the respective ends of the second transmission path 20 may each have a larger gate width than the semiconductor switches 41, 42, 43 and 44 connected to the points on the first transmission path 30. To be more specific, the total of the gate widths of the semiconductor switches 51 and 52 connected to the first transmission path 30 may be substantially equal to the total of the gate widths of the semiconductor switches 41, 42, 43 and 44 connected to the second transmission path 20.

According to the present example, the second transmission path 20 has a π attenuator, as the attenuator 21. The attenuator 21 includes a resistance 22 provided on the path of the second transmission path 20 and resistances 23 and 24 which are respectively provided between the ground potential and the respective ends of the resistance 22. As an alternative example, the attenuator 21 may be a T attenuator or the like. The attenuator 21 may have a variable attenuation amount. For example, the resistances included in the attenuator 21 may be variable resistances.

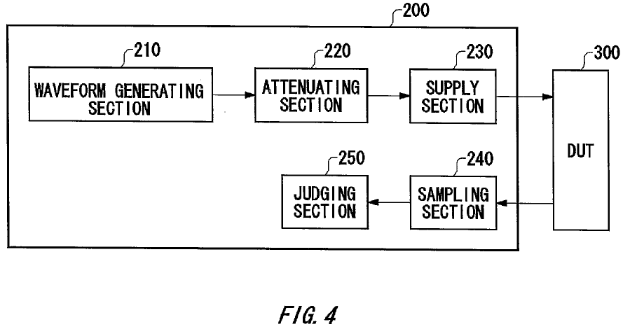

FIG. 4 illustrates an exemplary configuration of a test apparatus 200 relating to an embodiment of the present invention. The test apparatus 200 is used to test a device under test such as a semiconductor circuit. The test apparatus 200 includes therein a waveform generating section 210, an attenuating section 220, a supply section 230, a sampling section 240, and a judging section 250.

The waveform generating section 210 generates a test signal to be supplied to a device under test 300. For example, the waveform generating section 210 generates an analogue test signal. When the test apparatus 200 conducts a network analysis to measure the frequency characteristics of the device under test 300 such as the S parameters, for example, the waveform generating section 210 may sequentially generate test signals having different frequencies in order to sweep the frequency within a predetermined range for the measuring frequency.

The attenuating section 220 receives the test signal generated by the waveform generating section 210, attenuates the amplitude of the received test signal by a predetermined attenuation amount, and outputs the attenuated test signal. The attenuating section 220 may have the same functions and configuration as the attenuation apparatus 100 described with reference to FIGS. 1 to 3. For example, the attenuating section 220 receives the test signal generated by the waveform generating section 210 at the first terminal 78, attenuates the test signal by a predetermined attenuation amount, and outputs the attenuated test signal via the second terminal 79 to the supply section 230.

The attenuating section 220 may receive the first and second control signals CONT1 and CONT2 from a user or the like. Alternatively, the waveform generating section 210 or the like may generate the first and second control signals CONT1 and CONT2 based on a test program supplied to the test apparatus 200 in advance from the user or the like, prior to the generation of the test signal.

The supply section 230 supplies the test signal which has been attenuated by the attenuating section 220 to the device under test 300. For example, the supply section 230 may be a driver that generates a current to output or draw in accordance with the test signal.

The sampling section 240 samples the waveform of a response signal which is output from the device under test 300 in response to the test signal. When the test apparatus 200 conducts a network analysis of the device under test 300, the sampling section 240 may sample the test signal to be input into the device under test 300 via a directional coupler which is provided between the supply section 230 and the device under test 300. The sampling section 240 may be an AD converter that converts a signal input thereto into a digital signal.

The judging section 250 judges whether the device under test 300 passes or fails a test based on the result of the sampling performed by the sampling section 240. For example, the judging section 250 may calculate the frequency characteristics or the like of the device under test 300, such as the S parameter, based on the result of the sampling performed by the sampling section 240. The judging section 250 may judge whether the device under test 300 passes or fails a test by determining whether the calculated frequency characteristics satisfy a predetermined specification.

The test apparatus 200 relating to the present example can accurately attenuate the test signal, so as to accurately control the amplitude of the test signal. Therefore, the test apparatus 200 can accurately test the device under test 300. According to the above description, the test apparatus 200 generates an analogue test signal. However, the test apparatus 200 may be alternatively configured so as to generate a digital test signal.

While an aspect of the present invention has been described through the embodiments, the technical scope of the invention is not limited to the above described embodiments. It is apparent to persons skilled in the art that various alternations and improvements can be added to the above-described embodiments. It is also apparent from the scope of the claims that the embodiments added with such alternations or improvements can be included in the technical scope of the invention.

As clearly described in the above description, the attenuation apparatus 100 can accurately attenuate the signal and output the accurately attenuated signal. Also, the test apparatus 200 can accurately measure the characteristics of the device under test, and accurately test the device under test.

What is claimed is:

1. An attenuation apparatus for attenuating a signal received via a first terminal thereof and outputting the attenuated signal via a second terminal thereof, comprising:
a first transmission path and a second transmission path which respectively have different attenuation amounts for the signal;
a connection switching section that switches, between the first and second transmission paths, a transmission path connected to the first and second terminals so as to be positioned therebetween; and
a first ground connection switching section that connects, to a reference potential, respective ends of the first transmission path and a contact point positioned on a path between the respective ends of the first transmission path, when the second transmission path is electrically connected to the first and second terminals so as to be positioned therebetween.

2. The attenuation apparatus as set forth in claim 1, wherein
the first ground connection switching section connects, to the reference potential, the respective ends of the first transmission path and a plurality of contact points positioned on the first transmission path between the respective ends thereof, when the second transmission path is electrically connected to the first and second terminals so as to be positioned therebetween.

3. The attenuation apparatus as set forth in claim 2, wherein
the second transmission path has a larger attenuation amount than the first transmission path, and
the attenuation apparatus further comprises
a second ground connection switching section that connects respective ends of the second transmission path to the reference potential, but does not connect a wire between the respective ends of the second transmission path to the reference potential, when the first transmission path is electrically connected to the first and second terminals so as to be positioned therebetween.

4. The attenuation apparatus as set forth in claim 3, wherein
the first transmission path is a wire that electrically connects the respective ends of the first transmission path, and
the second transmission path has an attenuator between the respective ends thereof.

5. The attenuation apparatus as set forth in claim 2, wherein
the first ground connection switching section includes a plurality of semiconductor switches (I) that are provided between (i) the reference potential and (ii) the respective ends of the first transmission path and the plurality of contact points positioned between the respective ends of the first transmission path and (II) that are turned off when the first transmission path is electrically connected to the first and second terminals so as to be positioned therebetween.

6. The attenuation apparatus as set forth in claim 5, wherein
in such a state that the first transmission path is electrically connected to the first and second terminals so as to be positioned therebetween, the plurality of semiconductor switches are connected to the first transmission path with being positioned away from each other at such intervals that portions of a path between the first and second terminals to which the plurality of semiconductor switches are respectively connected have the same characteristic impedance.

7. The attenuation apparatus as set forth in claim 5, wherein
portions of a path between the first and second terminals to which the plurality of semiconductor switches are respectively connected are determined in such a manner that a reactance of an induction component of the path within each of the portions is equal to a reactance of a capacitance component of a corresponding one of the plurality of semiconductor switches which is connected to the each portion when the corresponding semiconductor switch is turned off.

8. The attenuation apparatus as set forth in claim 5, wherein
each of the plurality of semiconductor switches is a transistor whose drain and source are connected to the first transmission path and the reference potential so as to be positioned therebetween and whose gate is connected to a control signal line which controls a corresponding one of the plurality of semiconductor switches to be turned on or off, and
a total of gate widths of the plurality of semiconductor switches connected to the first transmission path is equal to a gate width of the semiconductor switch connected to the second transmission path.

9. A test apparatus for testing a device under test, comprising:
a waveform generating section that generates a test signal to be supplied to the device under test;
an attenuating section that attenuates the test signal;
a supply section that supplies the attenuated test signal to the device under test; and
a sampling section that samples a waveform of a response signal which is output from the device under test in response to the test signal, wherein
the attenuating section includes:
a first transmission path and a second transmission path which respectively have different attenuation amounts for a signal;
a connection switching section that switches, between the first and second transmission paths, a transmission path connected to a first terminal that receives a signal and a second terminal that outputs a signal so as to be positioned between the first and second terminals; and
a first ground connection switching section that connects, to a reference potential, respective ends of the first transmission path and a contact point positioned on a path of the first transmission path, when the second transmission path is electrically connected to the first and second terminals so as to be positioned therebetween.
